(19) United States
(12) Patent Application Publication
(10) Pub. No.: US 2026/0071322 A1
(43) Pub. Date: Mar. 12, 2026

(54) METHODS AND SYSTEMS FOR REMOVING DUST IN SEMICONDUCTOR FABRICATION

(71) Applicant: Taiwan Semiconductor Manufacturing Company, LTD., Hsinchu (TW)

(72) Inventors: Jia-Feng Lu, Taichung (TW); Fu-Chun Chang, Taichung (TW); Hao-Chin Cheng, Taichung (TW)

(21) Appl. No.: 18/882,876

(22) Filed: Sep. 12, 2024

(51) Int. Cl. C23C 16/44

(52) U.S. Cl. CPC C23C 16/4412; C23C 16/4401

(57) ABSTRACT

Dust traps are placed at elbows in the exhaust duct of a semiconductor fabrication plant. The dust trap is located below a top valve. This reduces dust buildup in the exhaust duct itself, reduces downtime, and provides ease of cleaning. Several different types of dust traps are described.

### BACKGROUND

Integrated circuits are formed on a semiconductor wafer. Photolithographic patterning processes use ultraviolet light to transfer a desired mask pattern to a photoresist on a semiconductor wafer. Etching processes may then be used to transfer to the pattern to a layer below the photoresist. This process is repeated multiple times with different patterns to build different layers on the wafer substrate and make a useful device. Dust may be created during the manufacturing process.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic illustration of an exhaust system, in accordance with some embodiments of the present disclosure.

FIG. 2A is a side view of a first embodiment of the dust collection system. FIG. 2B is a plan view of the system of FIG. 2A through line B-B.

FIG. 3A is a side view of a second embodiment of the dust collection system. FIG. 3B is a plan view of the system of FIG. 3A.

FIG. 4 is a side view of a third embodiment of the dust collection system.

FIG. 5 is a side view of a fourth embodiment of the dust collection system.

FIG. 6 is a side view of a fifth embodiment of the dust collection system.

FIG. 7 is a larger schematic illustration of the exhaust system.

FIG. 8 is a flow chart illustrating one method for collecting dust from an exhaust stream in a semiconductor fabrication plant, in accordance with some embodiments.

FIG. 9 is a flow chart illustrating one method for upgrading a dust collection system in a semiconductor fabrication plant, in accordance with some embodiments.

FIG. 10 is an illustrative side view showing an elbow of an exhaust duct being removed.

FIG. 11 is an illustrative side view showing a T-joint being inserted into the exhaust duct.

FIG. 12 is an illustrative side view showing a top valve being connected to the T-joint.

FIG. 13 is an illustrative side view showing a dust trap being connected below the top valve.

FIG. 14 is a schematic diagram of a CVD processing tool which can be connected to the exhaust system and the dust collection system of the present disclosure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g. “about 2 to about 4” also discloses the range “from 2 to 4.” The term “about” may refer to plus or minus 10% of the indicated number.

The terms “inlet” and “outlet” are relative to a fluid (e.g. liquid or gas) flowing through them with respect to a given structure, e.g. a fluid flows through the inlet into the structure and flows through the outlet out of the structure. The terms “upstream” and “downstream” are also relative to the direction in which a fluid flows through various components, i.e. the flow fluids through an upstream component prior to flowing through the downstream component. It should be noted that when a loop is present, a first component can be described as being both upstream of and downstream of a second component.

The term “fluidly connected” is used in the specification to indicate that two components are connected to each other in such a way that a fluid in one component will eventually reach the second component. This term permits other structures and components to be present between the two fluidly connected components.

The term “directly” is used to indicate that the fluid in the first component subsequently flows into the second component, with no other components between them that affect the makeup of the fluid.

The terms “horizontal” and “vertical” are used to indicate direction relative to an absolute reference, i.e. ground level. However, these terms should not be construed to require structures to be absolutely parallel or absolutely perpendicular to each other. For example, a first vertical structure and a second vertical structure are not necessarily parallel to each other. The terms “upwards” and “downwards” are also relative to an absolute reference; upwards is always against the gravity of the earth.

The present disclosure relates to methods and systems for improving dust collection in exhaust ducts of a semiconductor fabrication plant. Integrated circuits are typically formed by deposition and etching of various materials, for example various metals and dielectric materials or precursors such as silicon dioxide (SiO₂). These processing steps are performed in processing tools that perform different steps. Dust is generated in several of these processing tools and is subsequently removed in process waste gas. This waste gas forms an exhaust stream that travels through exhaust ducts due to negative pressure within the exhaust ducts. As the exhaust stream changes direction, particularly from a horizontal direction to a vertical direction, dust can fall out of the exhaust stream as the flow rate/wind speed decreases, leading to accumulation of dust at the elbows of the exhaust ducts. Dust buildup can cause pressure loss, in turn causing production machine/tool downtime as they must be shut down to clean the exhaust ducts. Besides reducing production capacity, product yield may also be affected due to excessive dust concentrations within the processing tools themselves. In the present disclosure, these issues are addressed by providing a dust trap at the elbows. This increases the volume in which dust can accumulate without affecting the path of the exhaust stream. In addition, cleaning can be performed without affecting the processing tools.

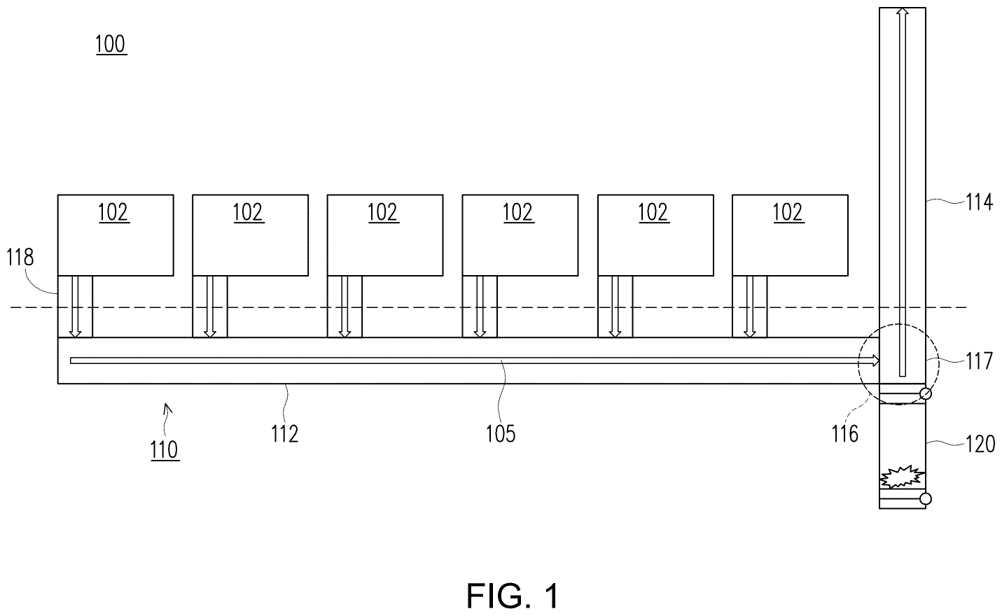

FIG. 1 is a schematic illustration of an exhaust system 100, in accordance with some embodiments of the present disclosure. Initially, the exhaust system includes an exhaust duct 110 having a horizontal section 112 and a vertical section 114 joined together at a joint 116. As used herein, the term “joint” refers to location of the exhaust dust where the exhaust stream changes direction. Here, the change in direction is from horizontal to vertical. This exhaust duct may also be considered an exhaust branch.

One or more semiconductor processing tools 102 are fluidly connected to the exhaust duct 110. Six such processing tools 102 are illustrated here, each having its own connection 118 to the exhaust duct 110, although any number of processing tools may be connected to the exhaust duct. As indicated by the dotted line, the processing tools 102 may be in the fab or “clean” area of the semiconductor fabrication plant, while some portions of the exhaust duct 110 are in the sub-fab below the fab area.

The processing tools may be, for example, a chemical vapor deposition (CVD) tool, a physical vapor deposition (PVD) tool, an etching tool, a diffusion furnace, or a photoresist stripper tool. Depending on the operation being performed, the process waste gas exiting such processing tools may include, for example, dust made of fine particles of solid matter. The dust may be composed of materials such as silicon dioxide (SiO₂), metals, and other precursor materials. Some non-limiting examples of metals may include copper, aluminum, nickel, chromium, gold, germanium, silver, titanium, tungsten, platinum, tantalum, ruthenium, cobalt, rhenium, palladium, or zirconium. Some non-limiting examples of precursor materials may include silanes, phosphine, boron, or carbon.

The gases flowing through the exhaust duct 110 are also referred to herein as an exhaust stream 105. Negative pressure in the exhaust duct 110 provides a force that causes the exhaust stream to flow. In particular embodiments, the negative pressure has a minimum value of about −400 Pa to about −600 Pa (with a higher negative value being desired). Generally, as the pressure becomes more positive, the pressure is insufficient to cause flow of the exhaust stream, and dust or other particles will not be carried away from the processing tools. The exhaust stream flows through the horizontal section 112 towards a joint 116. The joint 116 includes a surface 117 in the path of the exhaust stream. As the exhaust stream “hits” the surface, the exhaust stream is redirected upwards through the vertical section 114 of the exhaust duct. The velocity of the exhaust stream falls due to the turn. In addition, as a result, dust in the exhaust stream falls out of the exhaust stream and downwards due to gravity. A dust trap 120 is present below the joint 116. The dust trap can also be considered to be located below the horizontal section 112 of the exhaust duct.

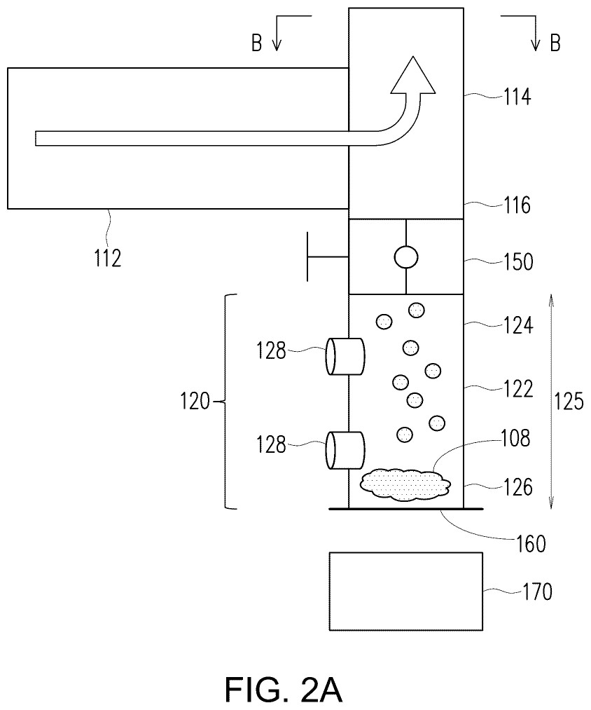

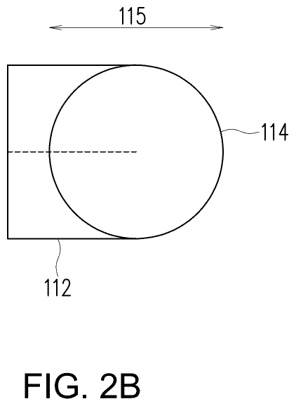

FIG. 2A and FIG. 2B are different views of a first embodiment of the dust collection system. As seen here, a top valve 150 (or damper) is located below the joint 116. Generally, any valve type that is suitable for use for powders/dust may be used for the top valve. For example, the top valve could be a gate valve, such as a slide valve or a knife valve. A gate valve includes a seat which can be sealed with a barrier or gate to shut off the flow. Alternatively, the top valve could be a pinch valve, which includes a rubber sleeve through which dust can flow. The rubber sleeve is located between surfaces that can either pull the sleeve open or push the sleeve together to close the valve. The top valve could also be a butterfly valve, in which a disc is positioned in the center of a pipe and rotated either parallel or perpendicular to the flow. The top valve could also be a rotary valve, such as a stopcock or a ball valve. The seat of a ball valve contains a ball with a passage running through its center. The ball can be pivoted to permit flow or block the flow through the body of the valve.

A dust trap 120 is located below the top valve 150. The dust trap is also located below the horizontal section 112 of the exhaust duct. The dust trap can be considered to be connected to the top valve as well. The dust trap 120 is formed from a cylindrical sidewall 122 having an upper end 124 and a lower end 126. The volume within the sidewall is substantially empty. One or more viewports 128 pass through the sidewall, so that the level of the dust collected within the dust trap can be determined. As illustrated here, two viewports 128 are present at different heights. Dust 108 is also illustrated accumulating within the dust trap. The dust trap could be made, for example, from lengths of pipe that are oriented vertically and sealed with valves.

In this embodiment, the bottom of the dust trap is formed from a bottom valve 160 that closes off the lower end of the volume surrounded by the sidewall 122. The bottom valve may also be any suitable type, such as those described for the bottom valve.

In particular embodiments, the dust trap has a height 125 of at least one (1) meter. However, it is contemplated that the height of the dust trap could be any desired value. For example, the height of the dust trap could range from 0.5 meters to about 3 meters, or from 1 meter to 1.5 meters. Other values and ranges are also within the scope of the present disclosure.

Referring now to FIG. 2B, the exhaust duct 110 generally has a cylindrical shape. As also seen here, the centerlines of the horizontal section 112 and the vertical section 114 intersect each other.

In particular embodiments, the diameter 115 of the exhaust duct (both the horizontal section and the vertical section 114) is from about 200 millimeters (mm) to about 300 mm. However, other ranges are within the scope of the present disclosure. By way of comparison, then, the height 125 of the dust trap is much greater than the diameter 115 of the exhaust duct, which increases the time between cleanings.

Referring to both FIG. 1 and FIG. 2A together, it is contemplated that in usage, the top valve 150 is left in the open position. When the dust trap needs to be emptied, the top valve 150 is closed and the bottom valve 160 is opened. Accumulated dust in the dust trap is emptied into a bin 170 or other suitable container for removal. In this way, the processing tools (see FIG. 1) can continue to be operated, and their exhaust may continue to flow while the dust trap is cleaned. The bottom valve is then closed, and the top valve is opened.

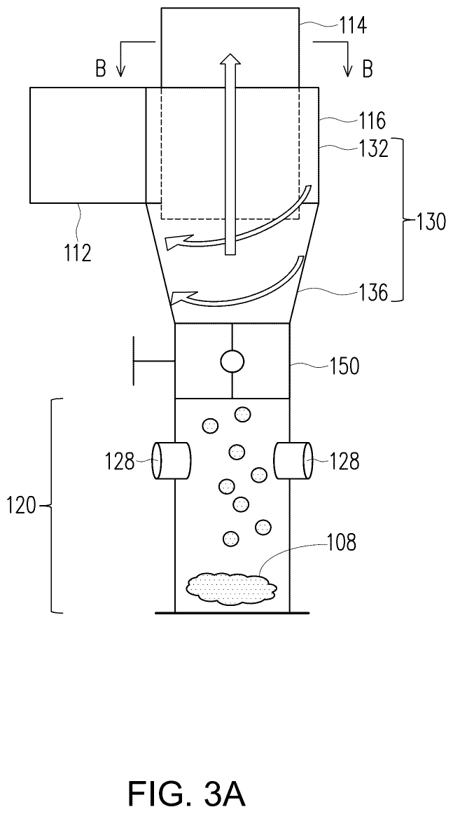

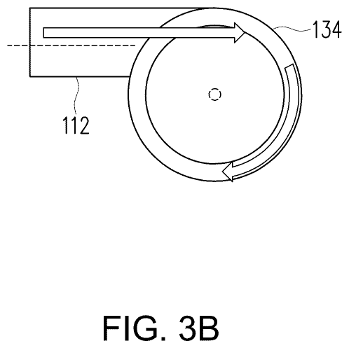

FIG. 3A and FIG. 3B are different views of a second embodiment of the dust collection system. Here, the joint 116 is in the form of a cyclone separator 130, or more specifically a reverse flow cyclone separator. The cyclone separator includes an upper cylindrical body 132 which is hollow and has an inlet offset from the center, such that the exhaust stream is received from the horizontal section 112 of the exhaust duct 110 upon a curved surface 134 that causes the exhaust stream to travel tangentially downwards through a lower conical body 136 which is also hollow. An outlet at the bottom of the conical body is covered by the top valve 150. The dust trap 120 is located below the top valve. The vertical section 114 of the exhaust duct enters and is partially located within the cyclone separator. After dust has fallen out of the exhaust stream, the exhaust stream continues upward through the vertical section 114. As also seen here, the centerlines of the horizontal section 112 and the vertical section 114 are offset from each other (see dashed lines). In addition, this embodiment is illustrated as having two viewports 128 at the same level, and on different sides of the dust trap 120.

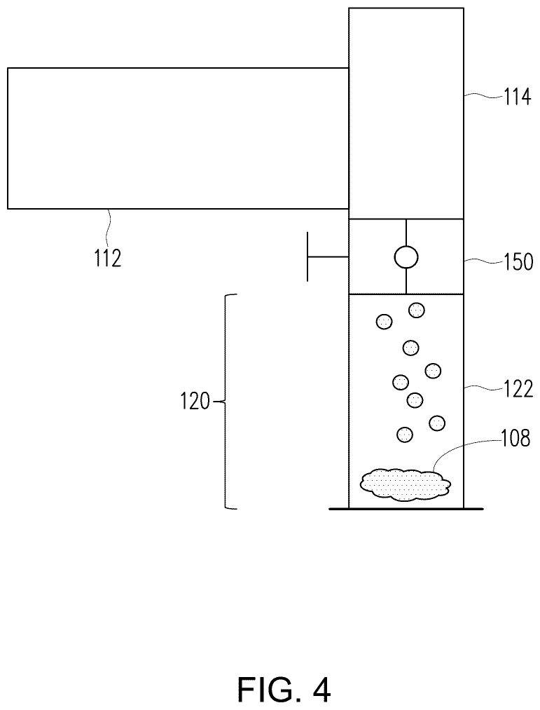

FIG. 4 is a side view of a third embodiment of the dust collection system. In this embodiment, the dust trap 120 does not contain viewports. Rather, the cylindrical sidewall 122 is made of a transparent material. This permits the dust level within the trap to be determined, so that the trap can be emptied when needed.

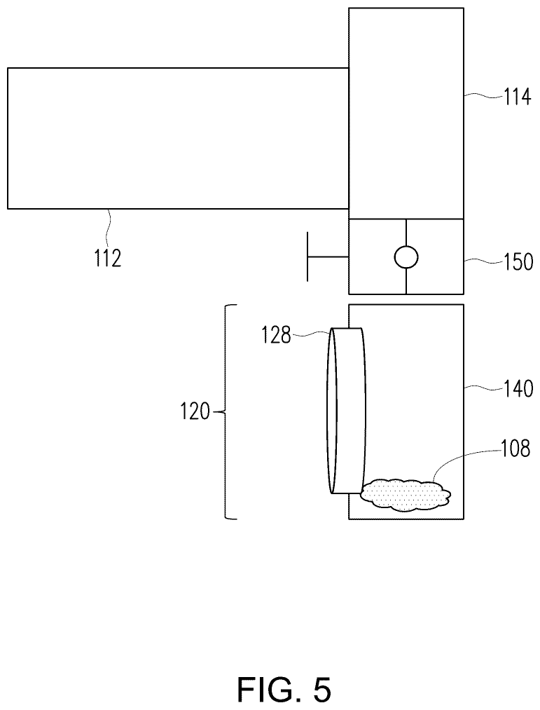

FIG. 5 is a side view of a fourth embodiment of the dust collection system. In this embodiment, no bottom valve 160 is present. Instead, it is contemplated that the dust trap 120 is a container 140 that can be easily separated from the top valve. For example, the dust trap could be screwed to the top valve (or some other release mechanism could be used). The dust trap could then be emptied when needed. In addition, the viewport 128 is illustrated as being elongated along the height axis of the container, rather than having multiple viewports.

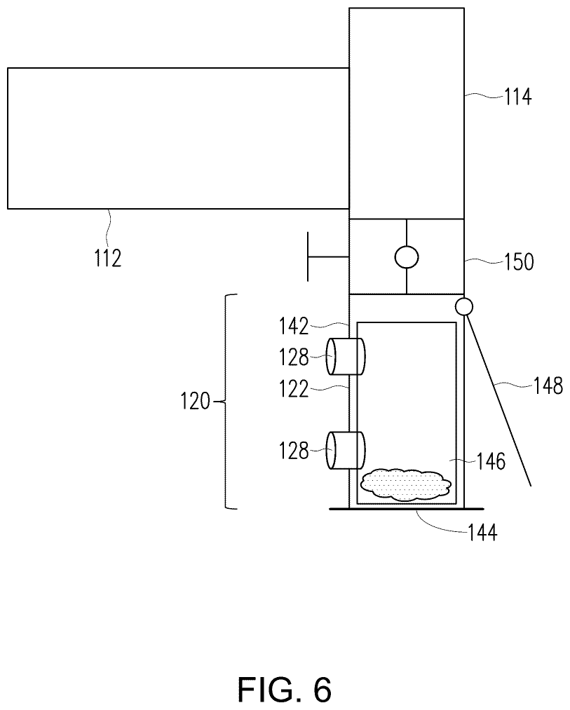

FIG. 6 is a side view of a fifth embodiment of the dust collection system. In this embodiment, the dust trap 120 includes a housing 142 formed from a cylindrical sidewall 122 and a floor 144. The housing is empty or hollow. A container 146 is located within the housing. The housing also contains a door 148, which is illustrated here as swinging upwards, but could also swing downwards or to the side as desired. It is contemplated that dust is deposited into the container, and the container can be removed through the door for emptying.

The various components of the exhaust duct and the dust trap can be made as desired from conventional materials, such as plastics and/or metals. The various components and their shapes and sizes can be made using conventional manufacturing techniques, and can be assembled using conventional techniques as well.

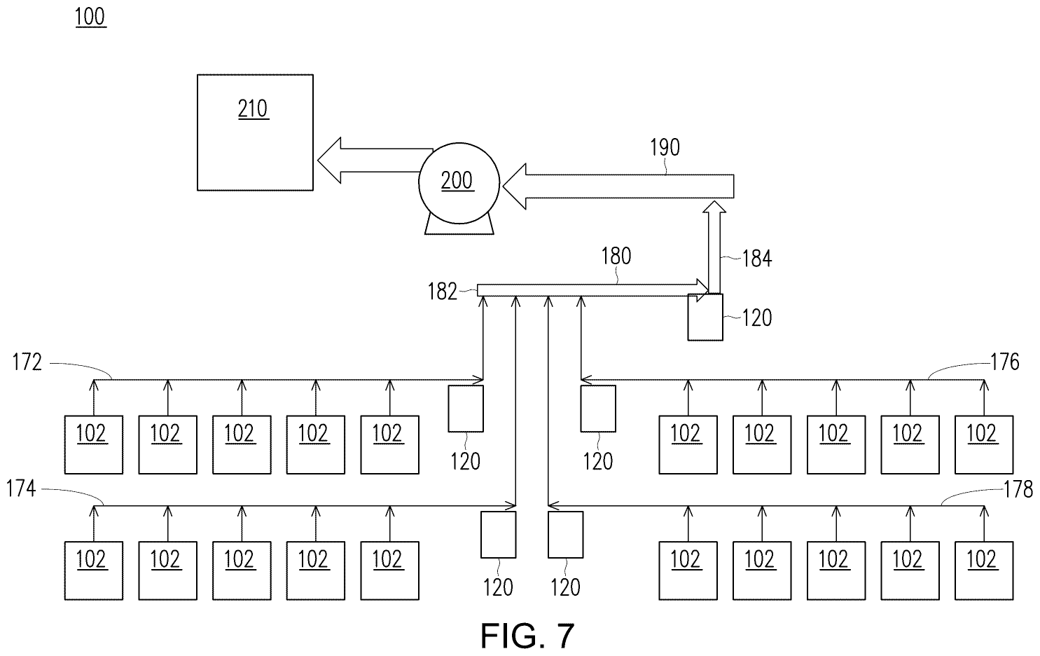

FIG. 7 is a larger schematic illustration of the exhaust system 100. Initially, four exhaust branches 172, 174, 176, 178 are illustrated, each exhaust branch corresponding to the exhaust duct 110 described in FIG. 1, and each branch having multiple semiconductor processing tools 102 connected thereto. Each exhaust branch includes an exhaust duct 110 with a dust trap 120 at the joint between the horizontal section and the vertical section. It is noted that a semiconductor fabrication plant may have several thousand processing tools, and so there may be several hundred dust traps 120 present to handle all of the tools.

Continuing, the vertical section of each exhaust branch is connected to a sub-main 180. The sub-main may also include a horizontal section 182 and a vertical section 184 and a dust trap 120 at their joint. The sub-main 180 connects to a head duct 190. Also illustrated is a pump or other source 200 for providing negative pressure to the exhaust branches. The head duct 190 connects to a central scrubber 210 for further cleaning of the exhaust streams. For example, a wet scrubber mixes the exhaust streams with water to precipitate materials into solids or to produce other materials which can be more easily treated or disposed of. For example, silicon dioxide precursors such as tetraethyl orthosilicate (TEOS) can be hydrolyzed into ethanol and silicic acid, which can be incinerated or released to waste water. The entire exhaust system for the semiconductor fabrication plant may have multiple sub-mains, head ducts, pumps, and/or central scrubbers as needed.

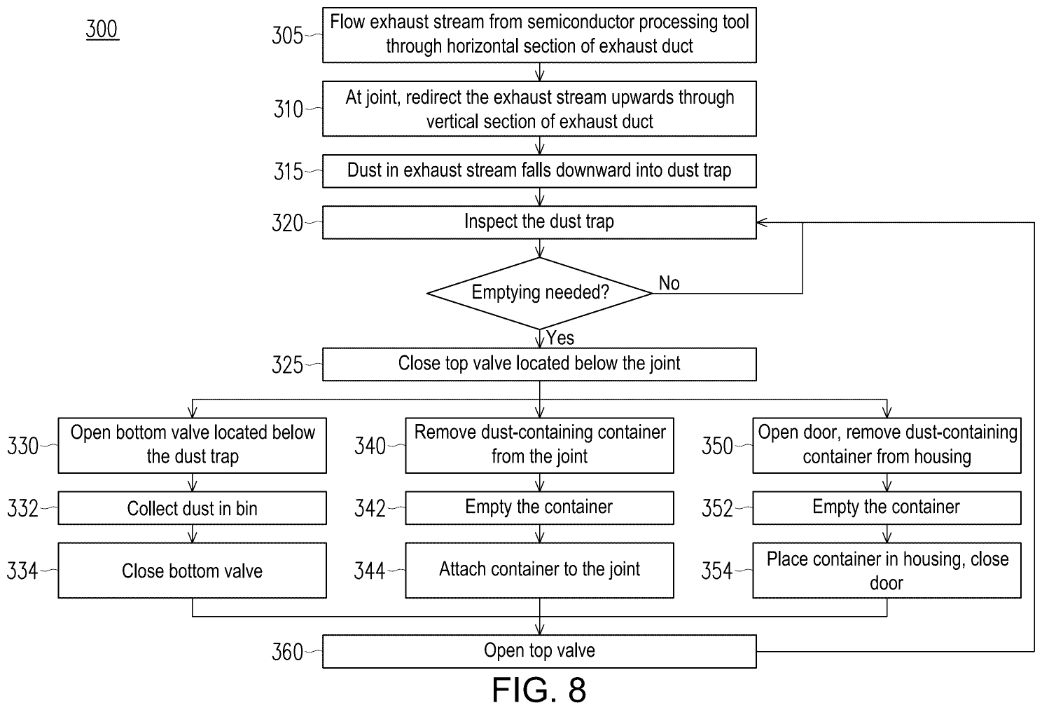

FIG. 8 is a flow chart illustrating one method 300 for collecting dust from an exhaust stream in a semiconductor fabrication plant, in accordance with some embodiments. Some steps of the method are also illustrated in FIGS. 1-6. While the method steps are discussed below in terms of collecting dust from one exhaust stream and a single exhaust duct, such discussion should also be broadly construed as applying to collection from multiple exhaust ducts. Methods using only some of the steps shown in the flow chart are also contemplated as falling within the present disclosure.

Initially, in step 305 of FIG. 8 and referring to FIG. 1, the exhaust stream flows from a semiconductor processing tool 102 through the horizontal section 112 of an exhaust duct 110. The exhaust stream contains dust, and heads towards a surface 117 of a joint 116. In step 310, the exhaust stream is redirected upwards through the vertical section 114 of the exhaust duct. This occurs, for example, due to the exhaust stream hitting the surface 117 of the joint. As a result, in step 315, the kinetic energy of the exhaust stream is reduced, and dust in the exhaust stream falls downward at the joint into the dust trap 120.

Next, in step 320 of FIG. 8, the dust trap is inspected to determine whether it needs to be emptied. This may be done, for example, by visual inspection through the viewports 128 illustrated in the embodiment of FIG. 2A or through the transparent sidewall 122 in the embodiment of FIG. 4. This inspection may be performed periodically in a manual fashion, for example every three months, or every six months, or every year. For example, in embodiments with viewports, dust accumulation that covers the lower viewport can be used as an indication that the dust trap should be emptied, while still providing a buffer volume for such maintenance to occur. Alternatively, electronic sensors could be used to monitor the level of dust accumulation within the trap and sound an alarm when emptying is needed. This could be done, for example, using sensors that determine the weight of the material in the dust trap or the level of dust accumulation. Such sensors could use light, ultrasound, or capacitance measurements, as examples of methods for making such determinations.

If the dust trap has not yet reached a level at which emptying should be performed, then nothing occurs. If it is determined that the dust trap should be emptied, then at step 325 the top valve 150 located below the joint is closed. Emptying can then be performed, depending on how the dust trap is set up.

For example, using the embodiment of FIG. 2A and FIG. 2B in which a bottom valve 160 is present, in step 330, the bottom valve is opened. In step 332, the dust is collected in a bin or other container. In step 334, the bottom valve is closed.

Alternatively, using the embodiment of FIG. 5 where the dust trap itself is a container 140 that can be separated, in step 340, the dust-containing container is separated or otherwise removed from the joint 116/top valve 150. In step 342, the container is emptied, for example into a bin or trash can or other container. In step 344, the now-empty container is attached back onto the joint/top valve.

As another example, for the embodiment of FIG. 6 in which a container 146 is located within a housing 142, in step 350 the door 148 is opened and the container 146 is removed from the housing. In step 352, the container is emptied. In step 354, the now-empty container is placed back into the housing and the door is closed.

Once the dust trap has been emptied, in step 360 of FIG. 8, the top valve 150 is then opened so that dust accumulation can begin again. One can then return to step 320 and inspect the dust trap again.

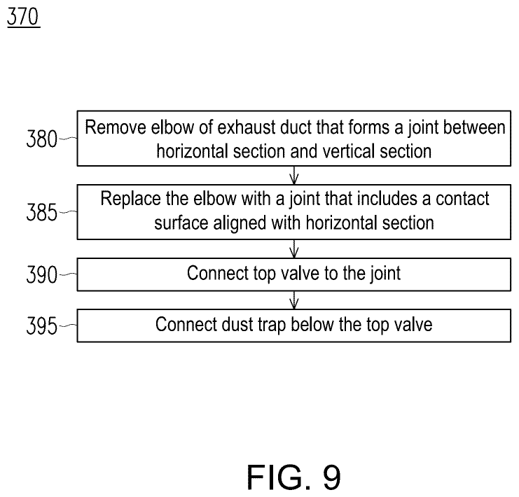

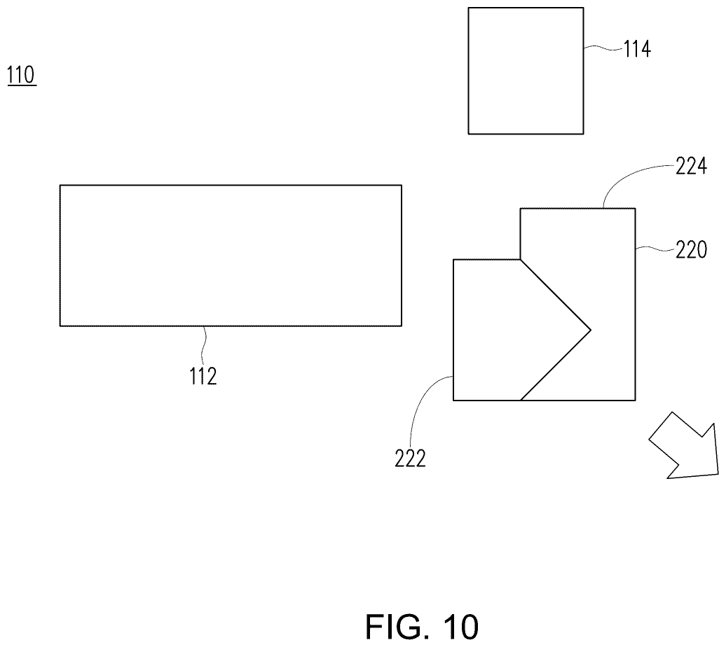

FIG. 9 is a flow chart illustrating a method 370 for upgrading a dust collection system in a semiconductor fabrication plant, in accordance with some embodiments. Some steps of the method are also illustrated in FIGS. 10-13. Methods using only some of the steps shown in the flow chart are also contemplated as falling within the present disclosure.

Referring initially to FIG. 10, the exhaust duct 110 includes a horizontal section 112 and a vertical section 114 which are joined together by an elbow 220. The elbow has only two ports 222, 224. In step 380 of FIG. 9, the elbow of the exhaust duct is removed, or in other words separated from the horizontal section 112 and the vertical section 114. It is noted the positions of the horizontal section and the vertical section are maintained by their connection to other components not illustrated here.

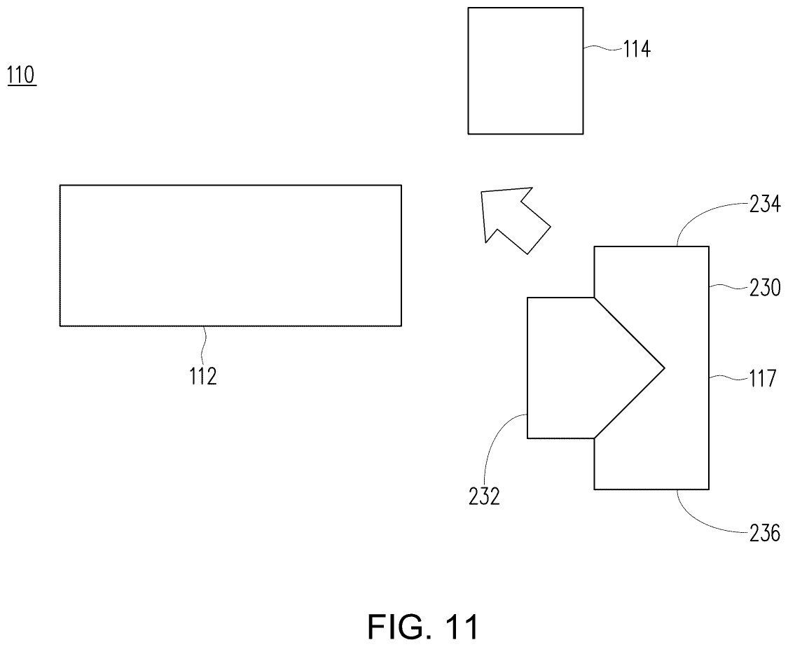

Next, in step 385 of FIG. 9 and with reference to FIG. 11, the elbow is replaced with a T-joint 230. The T-joint has three ports 232, 234, 236 which are connected to each other such that a stream entering any port can exit out of either one of the other two ports. The T-joint is oriented so that one of the ports 232 is horizontally aligned, and the other two ports 232, 234 are vertically aligned. In FIG. 11, the horizontal section 112 and the vertical section 114 will be joined to the T-joint at ports 232, 234. The T-joint also includes a contact surface 117 across from port 232 which will be aligned with the horizontal section. The cyclone separator 130 of FIG. 3A could also be considered to be a T-joint. Put another way, the T-joint is inserted between the horizontal section 112 and the vertical section 114.

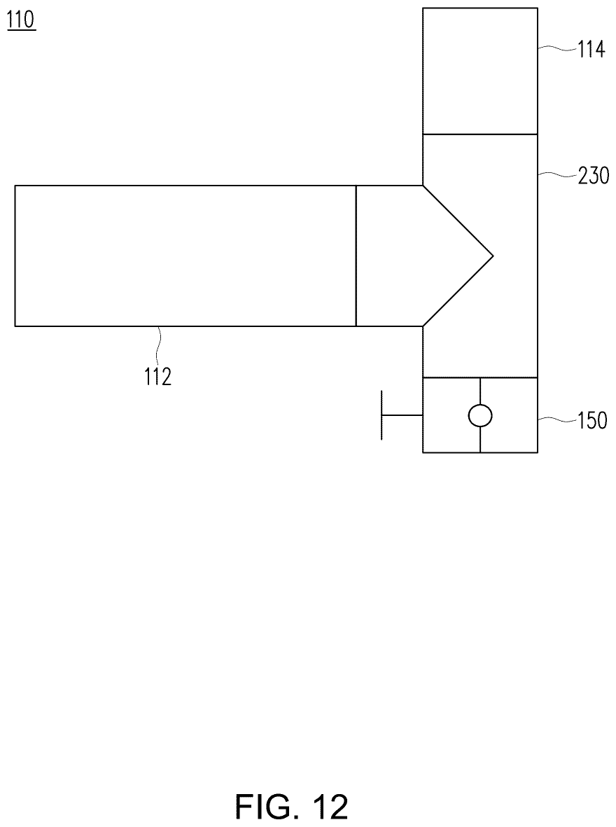

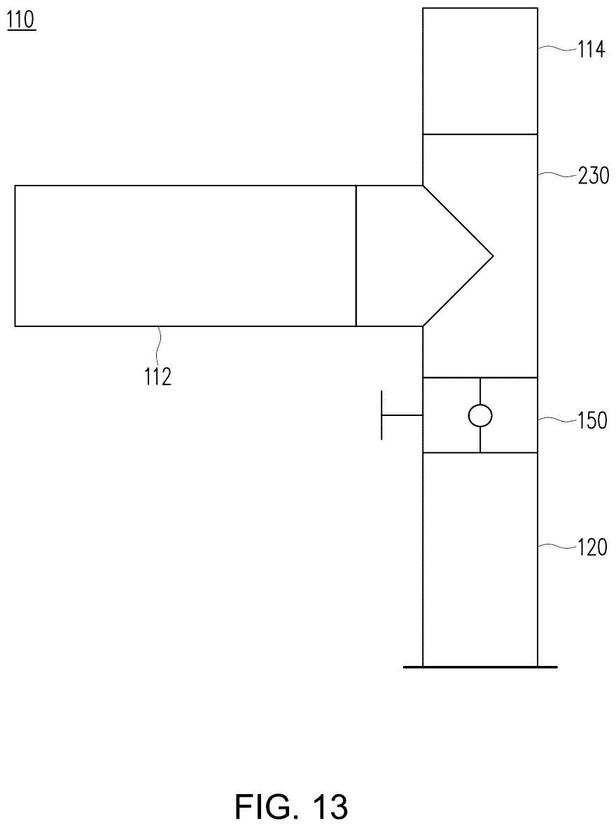

Next, in step 390 of FIG. 9 and with reference to FIG. 12, the top valve 150 is connected to the joint 230. The top valve thus seals off the lower vertical port of the joint. Then, in step 395 of FIG. 9 and as illustrated in FIG. 13, the dust trap 120 is connected below the top valve.

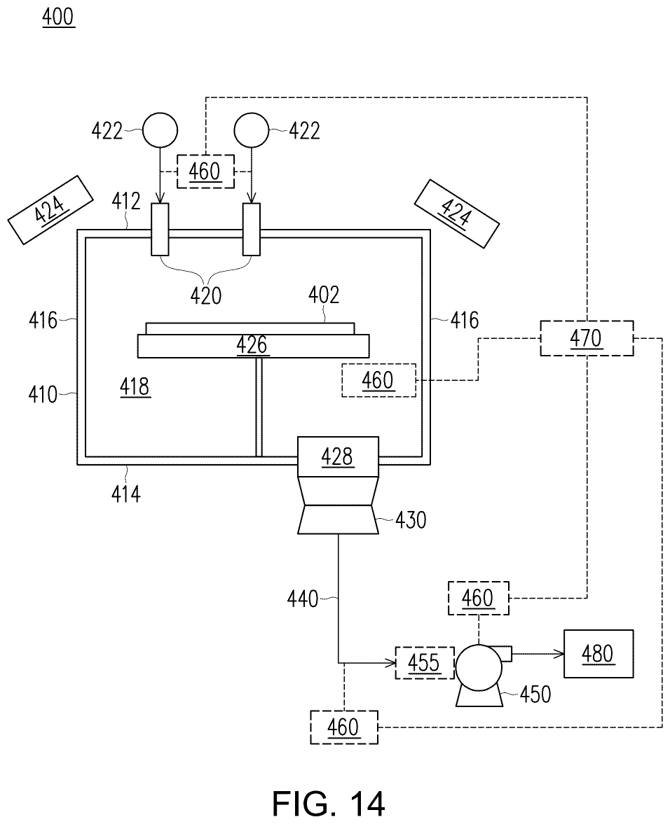

The dust collection system is used to transfer exhaust streams generated by semiconductor processing tools. FIG. 14 is an illustrative diagram of one such tool, a chemical vapor deposition (CVD) tool. CVD may be used, for example, to form electrically insulating silicon oxide (SiOx) layers of an integrated circuit on a semiconductor wafer substrate. A silicon-containing source gas acts as a silicon precursor, providing silicon for the reaction. Examples of such silicon precursors include but are not limited to tetraethyl orthosilicate (TEOS), trimethylsilane, tetramethylsilane, and hexachlorodisilane (HCDS). Ozone (O₃) is used to provide oxygen atoms for the reaction. At temperatures of about 300° C. to about 500° C. or higher, these gases will react to deposit silicon oxide.

Referring now to FIG. 14, the tool 400 includes a reaction chamber 410 having a top wall 412, a bottom wall 414, and side walls 416 that define an internal volume 418 of the reaction chamber. The reaction chamber 410 also includes one or more gas inlets 420 for the silicon source gas, O₃, and any other desirable gases. The gas inlets 420 are fluidly connected to gas sources 422 for providing the specified gas. It is noted that, for example, the silicon source gas and the O₃ may be mixed with carrier gases such as, for example, helium (H₂) or dioxygen (O₂).

The internal volume of the reaction chamber is heated to maintain the reaction gases (silicon precursor gas and ozone) in a gaseous state. This may be done, for example, by using heat lamps 424 or other radiant or convective heat sources. These heat sources may be located within the reaction chamber or its walls, or may be located external to the reaction chamber. For example, the walls of the reaction chamber could be made of a transparent heat-retaining material such as quartz.

Also included is a substrate support 426 within the reaction chamber, for supporting a semiconductor wafer substrate during the SACVD process. Also illustrated is a wafer substrate 402. In some embodiments, the substrate support may be an electrostatic chuck which uses electrostatic force to secure the wafer substrate. The substrate support may be rotatable in some embodiments, and may be configured to move up and down in other embodiments. For example, a lower position of the substrate support may be used for loading/unloading the wafer substrate. A raised position of the substrate support may be used to bring the substrate into a more suitable position for performing a processing step. For example, if the process gas inlets are located near the top wall, the raised position may place the substrate closer to the gas inlets. It is also noted that while only one substrate support is illustrated, any number of substrate supports may be present, so that multiple wafer substrates can be treated at a time.

An exhaust port 428 is also present for removing waste/exhaust gases from the reaction chamber. The exhaust port is also used to reduce the pressure within the reaction chamber. As illustrated here, the exhaust port 428 includes a valve 430 which is fluidly connected to an exhaust line 440 (corresponding to connection 118 of FIG. 1). The gas inlets and the exhaust port are typically located on different walls of the chamber. Various process sensors 460 may be present within the reaction chamber (for example, thermometer, pressure gauge, and/or flow meter).

A pump 450 is also illustrated here, which can be used to provide negative to the reaction chamber to withdraw the exhaust gases. Also illustrated here is an optional physical filter 455 which located upstream of the pump.

A controller 470 may be used to receive input from the sensors 460 to control the various gas flows, pressures, and temperatures to optimize the deposition process upon the semiconductor wafer substrate. The controller may be implemented on one or more general purpose computers, special purpose computer(s), a programmed microprocessor or microcontroller and peripheral integrated circuit elements, an ASIC or other integrated circuit, a digital signal processor, a hardwired electronic or logic circuit such as a discrete element circuit, a programmable logic device such as a PLD, PLA, FPGA, Graphical card CPU (GPU), or PAL, or the like. Such devices typically include at least memory for storing a control program (e.g. RAM, ROM, EPROM) and a processor for implementing the control program.

Deposition of silicon dioxide occurs upon the wafer substrate in the reaction chamber. The exhaust gases may also still contain reactive gases / molecules, and so reaction may continue occurring in the exhaust line as well, creating dust / powder in the exhaust stream.

The exhaust systems and dust collection systems of the present disclosure have several advantages. Accumulation of dust within the exhaust systems can trip operational alarms and interfere with normal operation, causing increased downtime due to maintenance and reducing overall wafer yield. Dust can also shorten the useful life of downstream components, such as the pump 200 of FIG. 7, or can require higher capital costs for equipment to treat larger volumes of waste. The use of the dust trap allows dust to accumulate without affecting the exhaust system. Cleaning of the dust trap can occur while the exhaust system continues to run, so there is no need to incur downtime for the semiconductor processing tools. The maintenance person does not need to be exposed to harmful gases that might be in the exhaust stream (such as hydrofluoric acid). The dust trap has no moving parts which could incur their own maintenance cycle, and preventive maintenance cycles for the exhaust system can be increased significantly.

Some embodiments of the present disclosure thus relate to methods for collecting dust from an exhaust stream in a semiconductor fabrication plant. The exhaust stream flows through a horizontal section of an exhaust duct towards a surface of a joint. The exhaust stream is redirected upwards through a vertical section of the exhaust duct. The dust in the exhaust stream falls downward at the joint into a dust trap.

Other embodiments disclosed herein relate to a dust collection system. An exhaust duct comprises a horizontal section and a vertical section fluidly connected to the horizontal section at a joint. A top valve is located below the joint. A dust trap is located below the top valve.

Also described in various embodiments herein are methods for upgrading a dust collection system in a semiconductor fabrication plant. An elbow of an exhaust duct that forms a joint between a horizontal section and a vertical section of an exhaust duct is removed. The elbow is replaced with a T-joint that includes a surface aligned with the horizontal section. A top valve is connected to the T-joint. A dust trap is connected below the top valve.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for collecting dust from an exhaust stream in a semiconductor fabrication plant, comprising:
flowing the exhaust stream through a horizontal section of an exhaust duct towards a surface of a joint; and
redirecting the exhaust stream upwards through a vertical section of the exhaust duct;
wherein the dust in the exhaust stream falls downward at the joint into a dust trap.

2. The method of claim 1, further comprising inspecting the dust trap to determine whether the dust trap needs to be emptied.

3. The method of claim 2, wherein the dust trap is inspected through one or more viewports, or through a transparent sidewall.

4. The method of claim 1, further comprising emptying the dust trap by:
closing a top valve located below the joint; and
opening a bottom valve located below the dust trap.

5. The method of claim 1, wherein the joint includes a cyclone separator.

6. The method of claim 1, wherein the exhaust stream is generated by one or more semiconductor processing tools.

7. The method of claim 1, wherein the pressure within the exhaust duct is maintained at a range of about −400 Pa to about −600 Pa.

8. The method of claim 1, wherein the dust is SiO₂.

9. The method of claim 1, wherein the exhaust duct has a diameter of about 200 mm to about 300 mm.

10. The method of claim 1, wherein the dust trap has a height of at least one meter.

11. The method of claim 1, wherein the dust trap is in the form of a container that is separable from the joint.

12. The method of claim 1, wherein the dust trap comprises a container that is located within a housing connected to the joint.

13. The method of claim 1, wherein the vertical section of the exhaust duct is connected to a sub-main which connects to a head duct which connects to a scrubber.

14. A dust collection system, comprising:
an exhaust duct comprising a horizontal section and a vertical section fluidly connected to the horizontal section at a joint;
a top valve located below the joint; and
a dust trap below the top valve.

15. The system of claim 14, wherein the horizontal section is fluidly connected to one or more semiconductor processing tools.

16. The system of claim 14, wherein the dust trap comprises a housing which is connected to the top valve at an upper side, and a bottom valve connected to a lower side of the housing.

17. The system of claim 16, wherein the housing includes one or more viewports arranged along a height of the housing.

18. The system of claim 14, wherein the vertical section of the exhaust duct is connected to a sub-main which connects to a head duct which connects to a scrubber.

19. A method for upgrading a dust collection system in a semiconductor fabrication plant, comprising:
removing an elbow of an exhaust duct that forms a joint between a horizontal section and a vertical section of an exhaust duct;
replacing the elbow with a T-joint that includes a surface aligned with the horizontal section; and
connecting a top valve to the T-joint; and
connecting a dust trap below the top valve.

20. The method of claim 19, wherein the exhaust duct is fluidly connected to one or more semiconductor processing tools selected from the group consisting of a CVD tool, a PVD tool, an etching tool, a diffusion furnace, and a photoresist stripper tool.
